(19) United States
(12) Patent Application Publication
(10) Pub. No.: US 2009/0128015 A1
(43) Pub. Date: May 21, 2009

(54) ORGANIC LIGHT EMITTING DEVICE

(76) Inventors: Hoon KIM, Hwaseong-si (KR); Won-Hoe Koo, Suwon-si (KR)

Correspondence Address: Haynes and Boone, LLP;IP Section, 2323 Victory Avenue, SUITE 700, Dallas, TX, 75219, US

(21) Appl. No.: 12/243,787

(22) Filed: Oct. 1, 2008

(30) Foreign Application Priority Data
Nov. 16, 2007 (KR) 10-2007-0117382

(51) Int. Cl. H01J 1/62

(52) U.S. Cl. 313/504

(57) ABSTRACT

An organic light-emitting device (“OLED”) improving adhesion of a frit is disclosed. The organic light-emitting device includes a first substrate, an auxiliary metallic layer disposed on a surface of the first substrate, a second substrate, a frit formed in overlapping relationship with the auxiliary metallic layer and interposed between the first and the second substrates to adhere the first and the second substrates together and wherein the auxiliary metallic layer is overlapped by the frit on the first substrate and formed separately from a wiring.

### CROSS-REFERENCE TO RELATED APPLICATIONS

This application claims priority under 35 U.S.C. §119 to Korean Patent Application No. 10-2007-0117382, filed on Nov. 16, 2007 in the Korean Intellectual Property Office (KIPO), the contents of which are herein incorporated by reference in their entirety.

### BACKGROUND OF THE INVENTION

1. Field of the Invention

The present invention relates to an organic light-emitting device. In particular, the present invention relates to an organic light-emitting device having a frit, or a fused or partially fused material.

2. Description of the Related Art

Display devices that display information onto a screen have been improved for high performance by becoming thinner, lighter, and more portable, aiding the development and progression of liquid crystal displays, one of the most important technologies of the modern information age. The Organic light emitting display (“OLED”) has developed as a substitute for the cathode ray tube (“CRT”) because the OLED is able to overcome negative aspects of the CRT such as heavy weight and great volume.

The OLED is a self light-emitting flat display device electrically exciting a fluorescent organic compound and emitting light. The OLED may be driven with a low voltage, and may be manufactured in a thin shape, and has merits such as a good viewing angle, a fast response speed and so on.

The OLED also includes a lower substrate and an upper substrate and a frit. The lower substrate is divided into a display region and a non-display region, and the upper substrate is disposed to face the lower substrate, and the frit is disposed between the lower and upper substrates to adhere the two substrates together. A plurality of light-emitting devices electrically connected to a plurality of metallic wirings is formed at the lower substrate. The light-emitting devices include an organic thin film layer having an anode electrode and a cathode electrode, a hole injection layer, a hole transportation layer, an electron transportation layer, an electron injection layer, and a light-emitting layer.

However, the OLED is vulnerable to hydrogen and oxygen since the OLED includes organic material, which may be easily oxidized by moisture in the air since the cathode electrode includes a metallic material, so that the electrical characteristics and the light-emitting characteristics of the OLED may be deteriorated. The OLED uses frits to seal the upper and lower substrates in order to prevent the intrusion of moisture, hydrogen and oxygen. The frit is melted by, for example, a laser or infrared light to adhere the two substrates together. The frit may not receive the heat energy evenly by an energy distribution according to laser characteristics. Thus, the frit has poor melting distribution and poor adhesion.

### SUMMARY OF THE INVENTION

The present invention provides an organic light-emitting device melting a frit evenly to improve adhesion of the upper and lower substrates of the organic light-emitting device.

In one aspect of the present invention, an organic light-emitting device (“OLED”) includes a first substrate having a wiring, a second substrate disposed on the first substrate, a frit and an auxiliary metallic layer. The frit is formed in overlapping relationship with the auxiliary metallic layer and interposed between the first and second substrates to adhere the first and the second substrates together. The auxiliary metallic layer is disposed on a surface of the first substrate and is formed separately from the wiring.

The wiring may include at least one of a gate line, a data line and a common voltage line.

The first substrate may include a display part to display an image and a peripheral part surrounding the display part.

The frit may be formed in the peripheral part and completely overlaps the auxiliary metallic layer and also overlaps a portion of the wiring.

The auxiliary metallic layer may comprise a plurality of dots.

The auxiliary metallic layer may comprise a plurality of spaced apart portions and further a shape of the spaced apart portions may be selected from the group consisting of: a circular shape, an elliptical shape and a polygonal shape.

Portions of the auxiliary metallic layer may also be formed at constant intervals across a width of the frit.

Portion of the auxiliary metallic layer may also be disposed more densely at adjacent edges of the frit than at a central portion of the frit.

The auxiliary metallic layer may be formed densely only at sides of the frit.

The auxiliary metallic layer may also include a plurality of holes.

The holes of the auxiliary metallic layer may be formed as one shape of a circular shape, an elliptical shape and a polygonal shape.

The holes may also be spaced apart at constant intervals across a width of the frit.

The holes may also be formed more densely at a central area of the frit than in an area adjacent to an edge of the frit.

The holes may also be formed densely only at a central area of the frit.

The frit may be melted to be adhered when a laser or an infrared ray is irradiated on the frit.

According to the present invention, an organic light-emitting device achieves uniform energy distribution of a laser, which is irradiated on a frit, by disposing a metallic layer under the frit. The frit is thus evenly melted and adhesion improves, and the intrusion of moisture, hydrogen and oxygen in air is stopped, so that defects such as changes in electrical and light-emitting characteristics may be prevented.

Moreover, the frit is melted by a low power laser, so that damage to the device and wirings under the frit may be prevented.

### BRIEF DESCRIPTION OF THE DRAWINGS

The above and other advantages of the present invention will become readily apparent by reference to the following detailed description when considered in conjunction with the accompanying drawings wherein:

FIG. 1 is a perspective view illustrating an OLED in accordance with an embodiment of the present invention;

FIG. 2 is a cross-sectional view illustrating an OLED in accordance with a first embodiment of the present invention;

FIG. 3 is a plan view illustrating the OLED in accordance with the first embodiment of the present invention;

FIG. 4 is a plan view illustrating an OLED in accordance with a second embodiment of the present invention;

FIG. 5 is a plan view illustrating an OLED in accordance with a third embodiment of the present invention;

FIG. 6 is a plan view illustrating an OLED in accordance with a fourth embodiment of the present invention;

FIG. 7 is a plan view illustrating an OLED in accordance with a fifth embodiment of the present invention;

FIG. 8 is a plan view illustrating an OLED in accordance with a sixth embodiment of the present invention; and

FIG. 9 is a plan view illustrating an OLED in accordance with a seventh embodiment of the present invention.

### DESCRIPTION OF THE EMBODIMENTS

The invention is described more fully hereinafter with reference to the accompanying drawings, in which embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected to or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be described in detail with reference to the accompanying drawings.

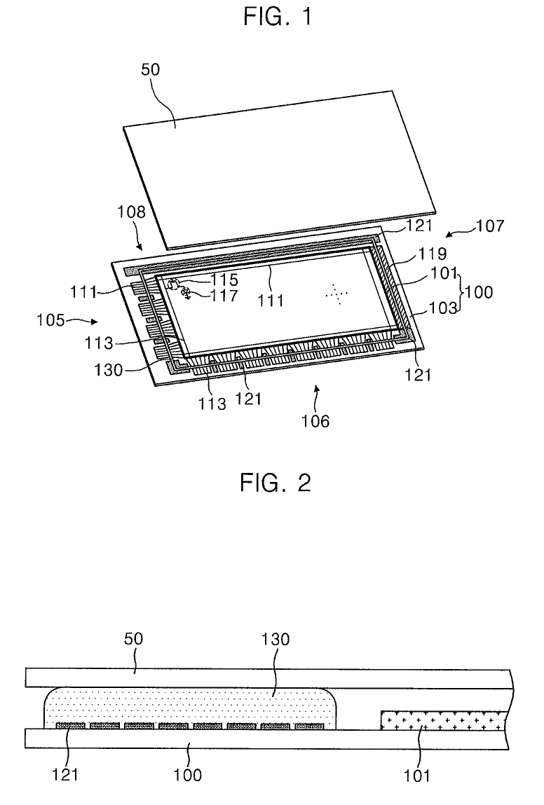

FIG. 1 is a perspective view illustrating an OLED in accordance with an embodiment of the present invention.

Referring to FIG. 1, the OLED in accordance with the embodiment of the present invention includes a first substrate 50 and a second substrate 100, which are adhered with each other through a frit 130.

The first substrate 50 includes an insulating material such as glass or plastic material, and is disposed on the second substrate 100. The first substrate 50 protects the second substrate from external shocks.

The second substrate 100 includes an insulating material such as glass or plastic materials, and is disposed under the first substrate 50. The second substrate 100 is divided into a display part 101 and a peripheral part 103.

The display part 101 includes a plurality of gate lines one of which is indicated by reference character 111, a plurality of data lines one of which is indicated by reference character 113 and a plurality of thin film transistors (“TFTs”), one for each pixel, and one of which is indicated by reference character 115 which is electrically connected to the gate line 111 and the data line 113 and an organic light-emitting part 117 electrically connected to the TFT 115. The intersection gate line 111 and the data line 113 define a pixel area, and the intersection of a plurality of gate and data lines define a plurality of pixels which are in a matrix form. The organic light-emitting part 117 includes an anode electrode layer, a cathode electrode layer facing the anode electrode layer and an organic light-emitting layer disposed between the two electrode layers.

The display part 101 may be formed as various forms of the OLED for displaying an image. For example, the display part 101 may be implemented as a passive matrix (“PM”) or alternatively as an active matrix (“AM”) as described by the above.

The peripheral part 103 is a non-display area surrounding the display part 101, and includes a frit 130, a gate line 111, a data line 113, a common voltage line 119 and first to fourth sides 105, 106, 107 and 108, respectively, which includes an auxiliary metallic layer 121.

Parts of the first side 105 and the second side 106 overlap with the frit 130. The gate line 111 and the data line 113, which are bound as a group to connect electrically to a driving device, are disposed at the first and second sides 105 and 106, and the auxiliary metallic layer 121 is disposed at the space between the groups of the gate lines 111 and the data lines 113. The third side 107 partially overlaps with the frit 130, and the common voltage line 119 is disposed at the third side 107 for providing a common voltage. The auxiliary metallic layer 121 formed beneath the frit 130 and overlapped by the frit 130 is disposed at the fourth side 108. The auxiliary metallic layer 121 is described below in detail.

Holes may be formed at the gate line 111, the data line 113, the common voltage line 119 and the auxiliary metallic layer 121 partially overlapping with the frit 130. The gate line 111, the data line 113, the common voltage line 119 and the auxiliary metallic layer 121 having holes is described below in detail.

The frit 130 is formed as a line around the periphery of the peripheral part 103 of the second substrate 100, and adheres the first substrate 50 to the second substrate 100. For example, the frit 130 may be formed over auxiliary metallic layer 121 on the second substrate 100 as a paste including a laser absorber, an organic binder or a filler. The frit 130 is melted by a laser or an infrared light to adhere the first substrate 50 to the second substrate 100.

The frit 130 overlaps with parts of the gate line 111, the data line 113, the common voltage line 119 and the auxiliary metallic layer 121. The frit 130 is formed to have suitable width and height for adhering the first substrate 50 to the second substrate 100.

Auxiliary metallic layer 121 may be composed of materials such as Al, Mo, Cu, or Ag which are formed on the surface of the second substrate 100 by sputtering and photolithography at the peripheral part 103. The auxiliary metallic layer 121 is formed in spaces between the groups of the gate lines 111 and the data lines 113, which are formed at the first and the second sides 105 and 106. The auxiliary metallic layer 121 extends in a horizontal direction and is overlapped by the frit 130, which is formed at the fourth side 108 of the peripheral part 103. The auxiliary metallic layer 121 may be formed as metallic groups having a dot shape. For example, the auxiliary metallic layer 121 may be formed as a plurality of metallic groups, and each of the groups may include one of a circle shape, an elliptical shape, and a polygonal shape.

The auxiliary metallic layer 121 of FIG. 1 is illustrated in an enlarged scale for convenience of description. The auxiliary metallic layer 121 is not limited to what is illustrated in FIG. 1, and the auxiliary metallic layer 121 may be separated from the gate line 111, the data line 113 and the common voltage line 119, and may be formed to overlap partially or totally with the frit 130.

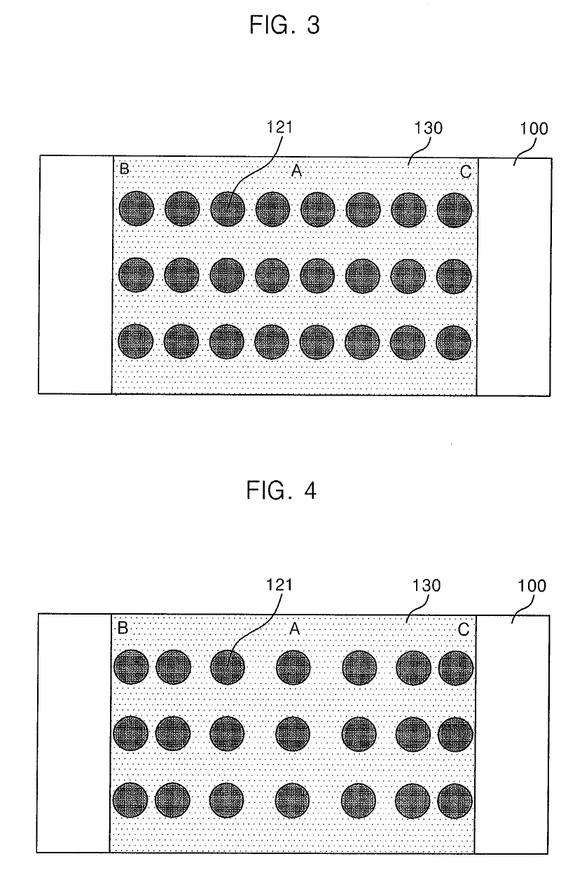

FIG. 2 is a cross-sectional view illustrating a peripheral portion of an OLED in accordance with a first embodiment of the present invention. FIG. 3 is a plan view of a peripheral portion of an OLED in accordance with the first embodiment of the present invention.

Referring to FIGS. 2 and 3, an auxiliary metallic layer 121 of an OLED in accordance with the first embodiment of the present invention is formed as a dot shape, and is disposed at constant intervals between the edges of frit 130.

The auxiliary metallic layer 121 is formed on a second substrate 100 to be overlapped by the frit 130. The auxiliary metallic layer 121 may be formed from a plurality of metallic groups, which is formed as one of a circle shape, an elliptical shape and a polygonal shape.

The auxiliary metallic layer 121 uniformly distributes energies provided to a center A and both sides B and C of the frit 130 when a laser is irradiated on the frit 130.

A width of a line of the frit 130 is formed to be less than a width of the laser beam which will be used to heat the frit 130. An amount of the laser energy provided to the center A of the frit 130 is greater than the amount of the laser energy provided to sides B and C is low. The frit 130 has difference energy distribution between the center A and sides B and C. The auxiliary metallic layer 121 guides uniform distribution of the energy of the center A and sides B and C, and assists in a uniform melting of the frit 130.

As will be appreciated by reference to FIG. 3, the dots of auxiliary metallic layer 121 are spaced apart at a constant interval in a width-wise direction of the frit 130. Thus, a higher energy area is formed, and the adhesion of the frit 130 is improved. The auxiliary metallic layer 121 decreases an amount of the laser energy irradiated on the frit 130 compared to when only the frit 130 is formed, so that damage to components of the second substrate 100 may be prevented.

The auxiliary metallic layer 121 is formed as a dot shape, and thus the weakness of the adhesion by metal and the frit 130 may be prevented. The adhesion is at a maximum level when the frit 130 adheres to a glass substrate, and the adhesion may be deteriorated when the auxiliary metallic layer 121 is completely formed. The auxiliary metallic layer 121 is formed as a dot shape to make the second substrate 100 contact the frit 130, so that the adhesion of the frit 130 is prevented from deteriorating.

When the laser is irradiated differently on the frit 130 overlapping with the gate line 111, the data line 113 and the common voltage line 119 from the frit 130 on the second substrate 100, the auxiliary metallic layer 121 is formed on the second substrate 100 to reduce the energy change of the laser. The auxiliary metallic layer 121 is formed to overlap with the frit 130 on the second substrate 100 having no metallic material, and reduces the energy amount of the laser irradiated on the frit 130, and prevents the energy change of the laser.

The first substrate 50, the second substrate 100 and the display part 101 in FIG. 2 is substantially the same in FIG. 1, so that a repetitive description is omitted.

FIG. 4 is a plan view illustrating a peripheral portion of an OLED in accordance with a second embodiment of the present invention.

Referring to FIG. 4, an auxiliary metallic layer 121 in accordance with the second embodiment of the present invention is formed as a dot shape, and is disposed closer to both sides B and C than to center A of the frit 130. The auxiliary metallic layer 121 may be formed as one of a circle shape, an elliptical shape and a polygonal shape.

The auxiliary metallic layer 121 uniformly distributes energies provided to the center A and both sides B and C of the frit 130 when a laser is irradiated on the frit 130. The auxiliary metallic layer 121 is disposed denser at both sides B and C of the frit 130 than at the center A of the frit 130, so that the energy, which distributes highly at the center A of the frit 130 and lowly at the sides B and C, automatically becomes uniform by the auxiliary metallic layer 121.

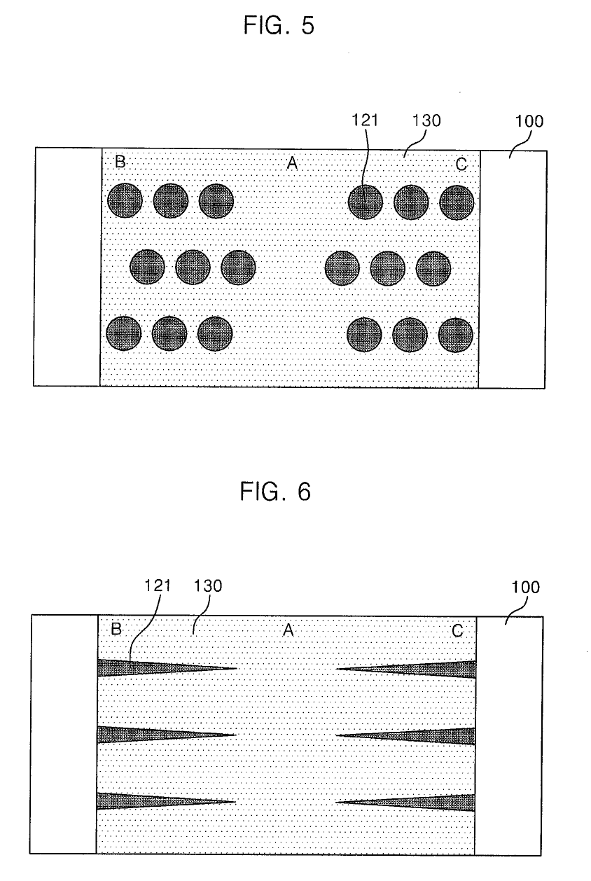

FIG. 5 is a plan view illustrating a peripheral portion of an OLED in accordance with a third embodiment of the present invention.

Referring to FIG. 5, an auxiliary metallic layer 121 in accordance with the third embodiment of the present invention is formed as a dot shape, and is disposed densely only at both sides B and C of the frit 130. The auxiliary metallic layer 121 may be formed as one of a circle shape, an elliptical shape and a polygonal shape.

The auxiliary metallic layer 121 highly distributes energy at sides B and C, at which the energy is distributed relatively lowly compared to the center A of the frit 130. Thus, the energy distribution at the center A and both sides B and C of the frit 130 becomes uniform.

Moreover, the auxiliary metallic layer 121 is not formed at the center A of the frit 130, so that adhesion between the second substrate 100 and the frit 130 is improved.

FIG. 6 is a plan view illustrating a peripheral portion of an OLED in accordance with a fourth embodiment of the present invention.

Referring to FIG. 6, an auxiliary metallic layer 121 in accordance with the fourth embodiment of the present invention is formed in a triangular shape, and is disposed to face each other with respect to a center A of the frit 130 within a line width of a line of the frit 130. The auxiliary metallic layer 121 is disposed in a direction of the width of the line of the frit 130, and a greater area may be disposed at sides B and C.

The auxiliary metallic layer 121 may compensate uniform energy distribution, which is not satisfied by a dot shape. The auxiliary metallic layer 121 is not limited to a triangular shape, and may be various shapes facing each other with respect to the center A of the frit 130.

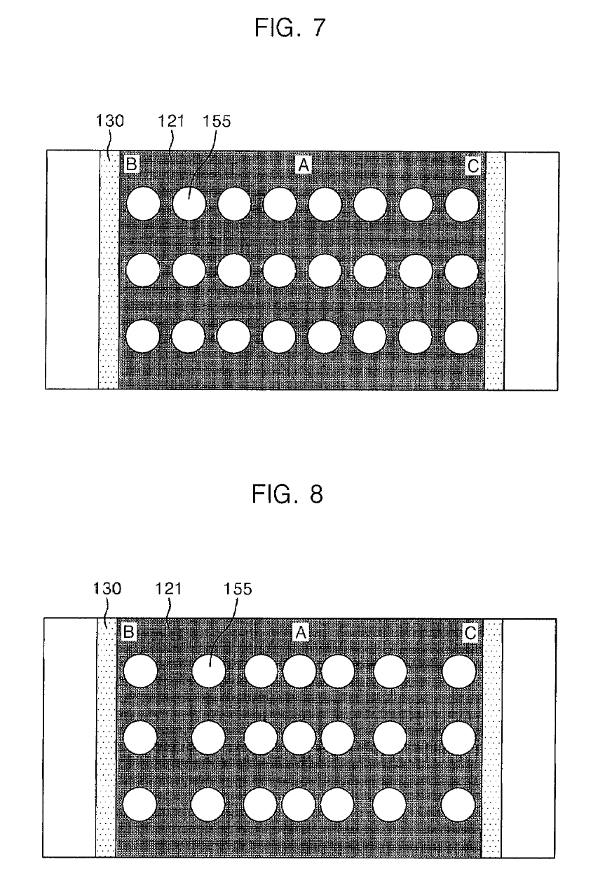

FIG. 7 is a plan view illustrating a peripheral portion of an OLED in accordance with a fifth embodiment of the present invention.

Referring to FIG. 7, an auxiliary metallic layer 121 in accordance with the fifth embodiment of the present invention overlaps with the frit 130, and includes a plurality of holes, one of which is indicated by reference character 155. The holes are disposed at constant intervals within a width of the frit 130. The holes may be formed as one of a circle shape, an elliptical shape and a polygonal shape. The auxiliary metallic layer 121 guides uniform energy distribution of the frit 130, and the adhesion between the frit 130 and second substrate 100 is improved.

FIG. 8 is a plan view illustrating a peripheral portion of an OLED in accordance with a sixth embodiment of the present invention.

Referring to FIG. 8, an auxiliary metallic layer 121 in accordance with the sixth embodiment of the present invention overlaps with the frit 130, and includes a plurality of holes, one of which is indicated by reference character 155. As will be appreciated by reference to FIG. 8, the density of holes near center A of the frit 130 is greater than the density of holes at sides B and C of the frit 130. This of course results in a greater amount of auxiliary metallic layer per unit area at sides B and C as compared to center A of the frit 130. The hole 155 may be formed as one of a circle shape, an elliptical shape and a polygonal shape at which the auxiliary metallic layer 121 and the frit 130 overlap with each other. The hole density arrangement at the center A of the frit 130 achieves better adhesion between the frit 130 and second substrate 100.

The hole 155 may be formed to align with a gate line, a data line or a common voltage line overlapping partially with the frit 130 as illustrated in FIG. 1.

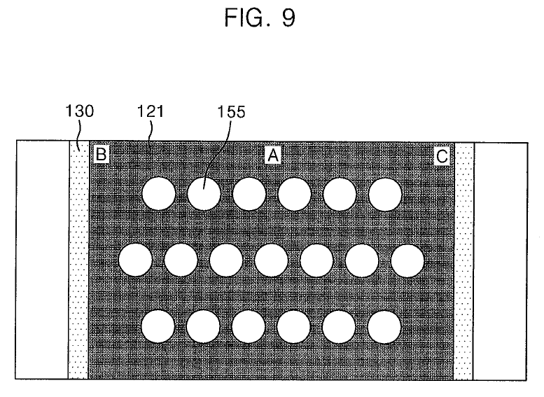

FIG. 9 is a plan view illustrating a peripheral portion of an OLED in accordance with a seventh embodiment of the present invention.

Referring to FIG. 9, an auxiliary metallic layer 121 in accordance with the seventh embodiment of the present invention overlaps with the frit 130, and includes a plurality of holes, one of which is indicated by reference character 155. In this embodiment, the hole density at a center A of the frit 130 is greater than the hole density at sides B and C of frit 130. The hole 155 may be formed as one of a circle shape, an elliptical shape and a polygonal shape at which the auxiliary metallic layer 121 and the frit 130 overlap with each other. The greater hole density at the center A of the frit 130 provides improved adhesion between the frit 130 and the second substrate 100.

The hole 155 may be formed at a gate line, a data line or a common voltage line overlapping partially with the frit 130 as illustrated in FIG. 1.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. An organic light-emitting device (“OLED”) comprising:
a first substrate having a wiring;
a second substrate;
an auxiliary metallic layer disposed on a surface of the first substrate; and
a frit formed in overlapping relationship with the auxiliary metallic layer and interposed between the first and second substrates to adhere the first and the second substrates together,
wherein the auxiliary metallic layer is formed separately from the wiring.

2. The OLED of claim 1, wherein the wiring comprises at least one of a gate line, a data line and a common voltage line.

3. The OLED of claim 2, wherein the first substrate comprises:
a display part; and
a peripheral part surrounding the display part.

4. The OLED of claim 3, wherein the frit is formed in the peripheral part and completely overlaps the auxiliary metallic layer and overlaps a portion of the wiring.

5. The OLED of claim 4, wherein the auxiliary metallic layer comprises a plurality of dots.

6. The OLED of claim 4, wherein the auxiliary metallic layer comprises a plurality of spaced apart portions and further wherein a shape of the spaced apart portions is selected from the group consisting of a circular shape, an elliptical shape and a polygonal shape.

7. The OLED of claim 6, wherein the portions of the auxiliary metallic layer are formed at constant intervals across a width of the frit.

8. The OLED of claim 6, wherein the portions of the auxiliary metallic layer are disposed more densely at adjacent edges of the frit than at a central portion of the frit.

9. The OLED of claim 6, wherein the auxiliary metallic layer is formed densely only at sides of the frit.

10. The OLED of claim 4, wherein the wiring and the auxiliary metallic layer include a plurality of holes.

11. The OLED of claim 10, wherein the holes are formed as one shape of a circular shape, an elliptical shape and a polygonal shape

12. The OLED of claim 10, wherein the holes are spaced apart at constant intervals across a width of the frit.

13. The OLED of claim 10, wherein the holes are formed more densely at a center area of the frit than in an area adjacent to an edge of the frit.

14. The OLED of claim 10, wherein the holes are formed densely only at a central area of the frit.

15. The OLED of claim 1, wherein the frit is melted to be adhered when a laser or an infrared ray is irradiated on the frit.
